(19) United States
(12) Patent Application Publication
(10) Pub. No.: US 2015/0348918 A1
(43) Pub. Date: Dec. 3, 2015

(54) PACKAGE SUBSTRATE, PACKAGE, PACKAGE ON PACKAGE AND MANUFACTURING METHOD OF PACKAGE SUBSTRATE

(71) Applicant: SAMSUNG ELECTRO-MECHANICS CO., LTD., Suwon (KR)

(72) Inventors: Jin Seon PARK, Suwon (KR); Seung Eun LEE, Suwon (KR); Mi Ja HAN, Suwon (KR); Seung Yeop KOOK, Suwon (KR); Je Gwang YOO, Suwon (KR); Ju Hee PARK, Suwon (KR); Jong Rip KIM, Suwon (KR); Myung Sam KANG, Suwon (KR)

(73) Assignee: SAMSUNG ELECTRO-MECHANICS CO., LTD., Suwon (KR)

(21) Appl. No.: 14/597,777

(22) Filed: Jan. 15, 2015

(30) Foreign Application Priority Data
May 30, 2014 (KR) 10-2014-0066375

(51) Int. Cl. H01L 23/64; H01L 21/50; H01L 25/065; H01L 23/00; H01L 23/498

(52) U.S. Cl. CPC H01L 23/642; H01L 24/48; H01L 23/49827; H01L 25/0657; H01L 21/50

(57) ABSTRACT

A package substrate, a package, a package on package, and a manufacturing method of a package substrate. A package substrate according to one exemplary embodiment includes: an insulating layer; a circuit layer formed on the insulating layer; and a capacitor including a lower electrode, an upper electrode, and a dielectric layer formed between the lower electrode and the upper electrode, the lower electrode and the dielectric layer being buried in the insulating layer and the upper electrode being formed on an upper portion of the insulating layer.

### CROSS-REFERENCE TO RELATED APPLICATIONS

This application claims the foreign priority benefit of Korean Patent Application No. 10-2014-0066375, filed on May 30, 2014, entitled “Package Substrate, Package, Package on Package and Manufacturing Method of Package Substrate” which is hereby incorporated by reference in its entirety into this application.

### BACKGROUND

1. Field

The present disclosure relates to a package substrate, a package, a package on package, and a manufacturing method of a package substrate.

2. Description of Related Art

In accordance with the rapid development of semiconductor technology, semiconductor devices have significantly grown. Further, development for a semiconductor package such as a system in package (SIP), a chip sized package (CSP), a flip chip package (FCP), or the like, configured as a package by mounting an electronic device such as the semiconductor device on a printed circuit board in advance, has been actively conducted. In addition, there is a package on package (POP) in which a controlling device and a memory device are implemented as a single package form in order to miniaturize high performance smart phones and improve performance thereof. The POP may be implemented by separately packaging the controlling device and the memory device, respectively, and then stacking and connecting the packages on each other.

### SUMMARY

Additional aspects and/or advantages will be set forth in part in the description which follows and, in part, will be apparent from the description, or may be learned by practice of the invention.

An aspect of the present disclosure may provide a package substrate, a package, a package on package, and a manufacturing method of a package substrate capable of improving shielding efficiency of a signal noise.

An aspect of the present disclosure may also provide a package substrate, a package, a package on package, and a manufacturing method of a package substrate capable of reducing a thickness.

According to an aspect of the present disclosure, a package substrate may include an insulating layer; a circuit layer formed on the insulating layer; and a capacitor including a lower electrode, an upper electrode, and a dielectric layer formed between the lower electrode and the upper electrode, the lower electrode and the dielectric layer being buried in the insulating layer and the upper electrode being formed on an upper portion of the insulating layer.

The insulating layer may have a two-layer structure including a first insulating layer and a second insulating layer, and the circuit layer may have a three-layer structure including a first circuit layer, a second circuit layer, and a third circuit layer.

According to another aspect of the present disclosure, a package may include an insulating layer; a circuit layer formed on the insulating layer; a capacitor including a lower electrode, an upper electrode, and a dielectric layer formed between the lower electrode and the upper electrode, the lower electrode and the dielectric layer being buried in the insulating layer and the upper electrode being formed on an upper portion of the insulating layer; and a device formed on the upper portion of the insulating layer and electrically connected to the circuit layer.

According to another aspect of the present disclosure, a package on package may include: a first package including an upper insulating layer, an upper circuit layer formed on the upper insulating layer, a first capacitor including a lower electrode, an upper electrode, and a dielectric layer formed between the lower electrode and the upper electrode, the lower electrode and the dielectric layer being buried in the upper insulating layer and the upper electrode being formed on an upper portion of the upper insulating layer, and a first device formed on the upper portion of the upper insulating layer and electrically connected to the upper circuit layer; a second package including a lower insulating layer, a lower circuit layer formed on the lower insulating layer, and a second device formed on the lower insulating layer and electrically connected to the lower circuit layer; and a connection terminal positioned between the first package and the second package and electrically connecting the first package and the second package to each other.

According to another aspect of the present disclosure, a manufacturing method of a package substrate may include: preparing a carrier substrate; forming a dielectric layer on a region of a portion of the carrier substrate; forming a lower electrode on the dielectric layer; forming a first insulating layer formed on the carrier substrate and burying the dielectric layer and the lower electrode; forming a first circuit layer on the first insulating layer; forming a second insulating layer on the first circuit layer; removing the carrier substrate; and forming a second circuit layer, an upper electrode, and a third circuit layer on the second insulating layer, the dielectric layer, and the first insulating layer, respectively.

According to another aspect of the present disclosure, a package substrate may include: an insulating layer; and a capacitor including a lower electrode, an upper electrode, and a dielectric layer formed between the lower electrode and the upper electrode, the lower electrode and the dielectric layer being recessed in the insulating layer from a first surface of the insulating layer, and the upper electrode being a portion of the capacitor protruded out of the first surface of the insulating layer. A lower circuit layer may be formed on a second surface of the insulating layer opposite to the first surface of the insulating layer; a via may be located between and electrically connecting the lower electrode of the capacitor to the lower circuit layer; and an upper circuit layer may be formed on the first surface of the insulating layer and substantially coplanar with the upper electrode of the capacitor.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view showing a package substrate according to an exemplary embodiment of the present disclosure;

FIGS. 2 through 11 are views showing a manufacturing method of a package substrate according to an exemplary embodiment of the present disclosure;

FIG. 12 is a view showing a package according to an exemplary embodiment of the present disclosure; and

FIG. 13 is a view showing a package on package according to an exemplary embodiment of the present disclosure.

### DESCRIPTION OF EMBODIMENTS

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### Package Substrate

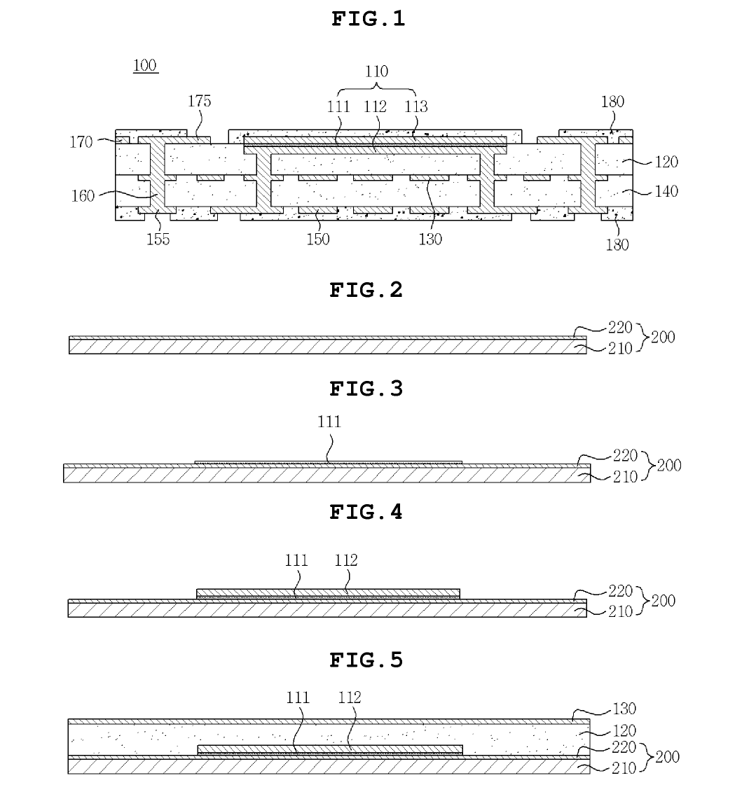

FIG. 1 is a view showing a package substrate according to an exemplary embodiment of the present disclosure.

Referring to FIG. 1, a package substrate 100 according to an exemplary embodiment of the present disclosure includes a first insulating layer 120, a second insulating layer 140, first circuit layer 130, second circuit layer 150, third circuit layer 170, a capacitor 110, a via 160, and a solder resist 180.

According to an exemplary embodiment of the present disclosure, the first insulating layer 120 and the second insulating layer 140 may be made of a complex polymer resin typically used as an interlayer insulating material. For example, the first insulating layer 120 and the second insulating layer 140 may be made of a prepreg, Ajinomoto Build up Film (ABF), and an epoxy based resin such as FR-4, Bismaleimide Triazine (BT), or the like. However, the material forming the first insulating layer 120 and the second insulating layer 140 according to an exemplary embodiment of the present disclosure is not limited thereto. The first insulating layer 120 and the second insulating layer 140 according to an exemplary embodiment of the present disclosure may be selected from insulating materials known in the field of circuit board.

As shown in FIG. 1, the first insulating layer 120 may be formed on an upper portion of the second insulating layer 140.

According to an exemplary embodiment of the present disclosure, the first circuit layer 130 is formed to be buried in the upper portion of the second insulating layer 140.

According to an exemplary embodiment of the present disclosure, the second circuit layer 150 is formed to be protruded from a lower portion of the second insulating layer 140. The second circuit layer 150 according to an exemplary embodiment of the present disclosure includes an external connection pad 155. The package substrate 100 according to an exemplary embodiment of the present disclosure and another package substrate (not shown) are electrically connected to each other through the external connection pad 155.

According to an exemplary embodiment of the present disclosure, the third circuit layer 170 is formed to be protruded from an upper portion of the first insulating layer 120. The third circuit layer 170 according to an exemplary embodiment of the present disclosure includes a bonding pad 175. The bonding pad 175 is a configuration that is electrically connected to a device (not shown) when the device (not shown) is mounted on an upper portion of the package substrate 100. For example, the bonding pad 175 may be connected to the device (not shown) by a wire bonding scheme.

The first circuit layer 130 to the third circuit layer 170 according to an exemplary embodiment of the present disclosure may be made of a conductive material used in the field of circuit board. For example, the first circuit layer 130 to the third circuit layer 170 may be made of copper (Cu).

In addition, according to an exemplary embodiment of the present disclosure, one layer of the first circuit layer 130 to the third circuit layer 170 may be a power layer and another of the layers may be a ground layer.

According to an exemplary embodiment of the present disclosure, the capacitor 110 is a thin film capacitor having a three-layer structure. The capacitor 110 according to an exemplary embodiment of the present disclosure includes an upper electrode 113, a lower electrode 112, and a dielectric layer 111. Here, the dielectric layer 111 is disposed between the upper electrode 113 and the lower electrode 112.

The upper electrode 113 of the capacitor 110 according to an exemplary embodiment of the present disclosure is formed on the upper portion of the first insulating layer 120. That is, the upper electrode 113 of the capacitor 110 and the third circuit layer 170 are formed on the same layer. In addition, the dielectric layer 111 and the lower electrode 112 according to an exemplary embodiment of the present disclosure are formed to be buried (e.g., recessed) in the first insulating layer 120.

The upper electrode 113 of the capacitor 110 formed as described above is bonded to a portion of the third circuit layer 170 formed on the same layer, which is not shown. For example, the portion of the third circuit layer 170 bonded to the capacitor 110 may be the bonding pad 175. In addition, in the case in which the third circuit layer 170 bonded to the capacitor 110 is the power layer, the upper electrode 113 of the capacitor 110 may also serve as the power layer.

According to an exemplary embodiment of the present disclosure, the via 160 electrically connects at least two of the first to third circuit layers 130 to 170 and the capacitor 110 to each other.

Referring to FIG. 1, the via 160 according to an exemplary embodiment of the present disclosure electrically connects the lower electrode 112 of the capacitor 110 and the first and second circuit layers 130 and 150 to each other. In addition, the via 160 electrically connects the second circuit layer 150 and the third circuit layer 170 to each other. Although not shown in FIG. 1, the via 160 connects the first circuit layer 130 and the second circuit layer 150 to each other or the first circuit layer 130 and the third circuit layer 170 to each other.

According to an exemplary embodiment of the present disclosure, the solder resist 180 is formed to surround the second circuit layer 150, the third circuit layer 170, and the capacitor 110 except for a region connected to the outside. Here, the region connected to the outside is the bonding pad 175 and the external connection pad 155.

Although an exemplary embodiment of the present disclosure illustrates a case in which the package substrate 100 is formed by the insulating layer of the two layers and the circuit layer of the three layers, the present disclosure is not limited thereto. That is, the number of layers of the package substrate 100 may be variously implemented according to a selection of those skilled in the art.

### Manufacturing Method of Package Substrate

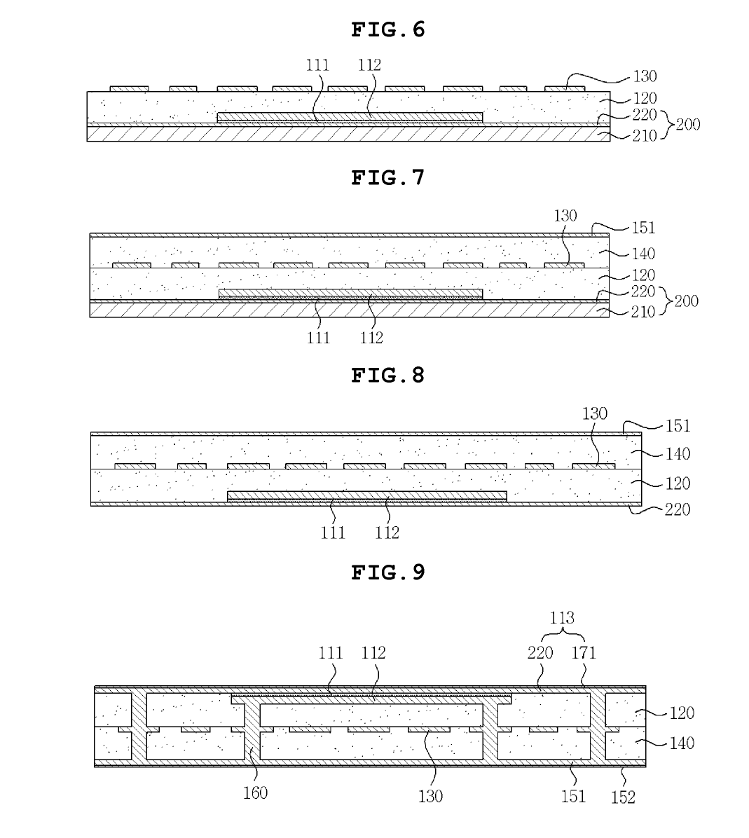

FIGS. 2 through 11 are views showing a manufacturing method of a package substrate according to an exemplary embodiment of the present disclosure.

Referring to FIG. 2, a carrier substrate 200 is provided.

According to an exemplary embodiment of the present disclosure, the carrier substrate 200 has a carrier core 210 and a carrier metal layer 220 formed thereon.

According to an exemplary embodiment of the present disclosure, the carrier core 210 is to support the insulating layers, the circuit layers, and the like of the package substrate when forming the insulating layers, the circuit layers, and the like of the package substrate. The carrier core 210 according to an exemplary embodiment of the present disclosure is removed in an intermediate process in which the package substrate is formed later or after the formation of the package substrate is completed. The carrier core 210 according to an exemplary embodiment of the present disclosure may be made of an insulating material or a metal material, or may be formed in a structure in which the insulating material and the metal material are stacked. However, the carrier core 210 is not limited thereto, but any carrier core may be used as long as it is a carrier used as a supporting substrate in the field of circuit board and removed later.

According to an exemplary embodiment of the present disclosure, the carrier metal layer 220 may be made of copper. However, a material of the carrier metal layer 220 is not limited to copper and any material may be used without being limited as long as it is used as a conductive material for a circuit in the field of circuit board.

Although an exemplary embodiment of the present disclosure illustrates a case in which the carrier substrate 200 has a structure including both the carrier core 210 and the carrier metal layer 220, the carrier substrate 200 may, for example, be configured as having only the carrier core 210. In this case, the carrier substrate 200 according to an exemplary embodiment of the present disclosure may be prepared by separately forming the carrier metal layer 220 on the carrier core 210.

Referring to FIG. 3, the dielectric layer 111 is formed on the carrier substrate 200.

The dielectric layer 111 according to an exemplary embodiment of the present disclosure is formed on the carrier metal layer 220 of the carrier substrate 200. In addition, the dielectric layer 111 is formed on a portion of the carrier metal layer 220. Here, the portion of the carrier metal layer 220 on which the dielectric layer 111 is formed is a region on which the capacitor (not shown) is to be formed. According to an exemplary embodiment of the present disclosure, the dielectric layer 111 may be made of a dielectric material on the carrier metal layer 220 by a depositing method or a printing method.

Referring to FIG. 4, the lower electrode 112 is formed on the dielectric layer 111.

The lower electrode 112 according to an exemplary embodiment of the present disclosure may be formed by an electroless plating method and an electroplating method. In addition, the lower electrode 112 is made of copper. However, a material of the lower electrode 112 is not limited to copper and any material may be used without being limited as long as it is used as a conductive material for a circuit in the field of circuit boards.

Referring to FIG. 5, the first insulating layer 120 and the first metal layer 131 are formed.

According to an exemplary embodiment of the present disclosure, the first insulating layer 120 is formed on the carrier metal layer 220 so as to bury the dielectric layer 111 and the lower electrode 112. The first insulating layer 120 is made of a complex polymer resin typically used as an interlayer insulating material. For example, the first insulating layer 120 is made of a prepreg, Ajinomoto Build up Film (ABF), and an epoxy based resin such as FR-4, Bismaleimide Triazine (BT), or the like. However, a material forming the first insulating layer 120 according to an exemplary embodiment of the present disclosure is not limited thereto, and may be selected from insulating materials known in the field of circuit board.

According to an exemplary embodiment of the present disclosure, the first metal layer 131 is formed on the first insulating layer 120. The first metal layer 131 according to an exemplary embodiment of the present disclosure is made of copper. However, a material of the first metal layer 131 is not limited to copper and any material may be used without being limited as long as it is used as a conductive material for a circuit in the field of circuit board. The first metal layer 131 may be formed by an electroless plating method and an electroplating method. Alternatively, the first metal layer 131 may be formed by a lamination method. The forming method of the first metal layer 131 according to an exemplary embodiment of the present disclosure is not limited to the methods as described above, and any method may be used as long as it may form the metal layer on the insulating layer in the field of circuit board.

Referring to FIG. 6, the first circuit layer 130 is formed.

According to an exemplary embodiment of the present disclosure, the first circuit layer 130 is formed by patterning the first metal layer (131 of FIG. 5). For example, an etching resist (not shown) is first formed on the first metal layer (131 of FIG. 5). The etching resist (not shown) is patterned to protect a region on the first metal layer (131 of FIG. 5) in which a circuit pattern is to be formed and to position an opening part in a region from which the circuit pattern is to be removed. Next, the first circuit layer 130 is formed by removing the first metal layer (131 of FIG. 5) exposed by the opening part of the etching resist (not shown) and removing the etching resist (not shown).

Referring to FIG. 7, the second insulating layer 140 and the second metal layer 151 are formed.

According to an exemplary embodiment of the present disclosure, the second insulating layer 140 is formed on the first insulating layer 120 and the first circuit layer 130. The second insulating layer 140 according to an exemplary embodiment of the present disclosure may be made of a complex polymer resin typically used as an interlayer insulating material. For example, the second insulating layer 140 may be formed of a prepreg, Ajinomoto Build up Film (ABF), and an epoxy based resin such as FR-4, Bismaleimide Triazine (BT), or the like. However, a material forming the second insulating layer 140 according to an exemplary embodiment of the present disclosure is not limited thereto, and may be selected from insulating materials known in the field of circuit board. The second insulating layer 140 according to an exemplary embodiment of the present disclosure may be made of the same material as the first insulating layer 120 or may also be made of a material different from the material of the first insulating layer 120.

According to an exemplary embodiment of the present disclosure, the second metal layer 151 is formed on the second insulating layer 140. The second metal layer 151 according to an exemplary embodiment of the present disclosure is made of copper. However, a material of the second metal layer 151 is not limited to copper and any material may be used without being limited as long as it is used as a conductive material for a circuit in the field of circuit board.

In addition, according to an exemplary embodiment of the present disclosure, the second metal layer 151 may be formed by a lamination method. However, the forming method of the second metal layer 151 is not limited to the methods as described above, and any method may be used as long as it may form the metal layer on the insulating layer in the field of circuit board.

By the second insulating layer 140 formed as described above, the first circuit layer 130 is buried in the second insulating layer 140.

Referring to FIG. 8, the carrier core 210 is removed.

According to an exemplary embodiment of the present disclosure, the carrier core (210 of FIG. 7) is removed by separating the carrier core (210 of FIG. 7) and the carrier metal layer 220 from each other.

In this case, the carrier metal layer 220 is remained on the first insulating layer 120 as it is.

Referring to FIG. 9, the via 160 is formed.

According to an exemplary embodiment of the present disclosure, the via 160 simultaneously connects the lower electrode 112, the first circuit layer 130, and the second metal layer 151 to one another. In addition, the via 160 simultaneously connects the carrier metal layer 220, the first circuit layer 130, and the second metal layer 151 to one another.

According to an exemplary embodiment of the present disclosure, a via hole (not shown) penetrating through the second metal layer 151, the second insulating layer 140, the first circuit layer 130, and the first insulating layer 120 is first formed. In this case, a bottom of the via hole (not shown) becomes the carrier metal layer 220 or the lower electrode 112 depending on a position at which the via hole (not shown) is formed.

Next, the via 160 is formed by filling the via hole (not shown) with a conductive material. For example, the via 160 may be formed by filling the via hole (not shown) with conductive paste by a printing method. Alternatively, the via 160 may be formed by filling the via hole (not shown) with a conductive metal by an electroless plating method and an electroplating method.

According to an exemplary embodiment of the present disclosure, the via 160 is made of copper. However, a material of the via 160 is not limited to copper and any material may be used as long as it is any one of known conductive materials in the field of circuit board.

According to an exemplary embodiment of the present disclosure, when the via 160 is formed, a first plating layer 171 is formed on the carrier metal layer 220. In addition, a second plating layer 152 is formed on the second metal layer 151. The first plating layer 171 and the second plating layer 152 according to an exemplary embodiment of the present disclosure may be formed by a separate process after the via 160 is formed. Alternatively, the first plating layer 171 and the second plating layer 152 according to an exemplary embodiment of the present disclosure may be formed simultaneously with the via 160 by an electroless plating process and an electroplating process for forming the via 160.

Although an exemplary embodiment of the present disclosure illustrates a case in which the via 160 is formed after both the first insulating layer 120 and the second insulating layer 140 are stacked, the present disclosure is not limited to the above-mentioned order. That is, the via 160 according to an exemplary embodiment of the present disclosure may be formed in a stack via form having a structure in which the via is separately formed on each insulating layer by a selection by those skilled in the art and is stacked on each other. Alternatively, in the case in which a plurality of vias 160 are formed, both the stack via structure and a through via structure in which the via is formed in the first insulating layer 120 and the second insulating layer 140 at a time may be included.

Referring to FIG. 10, the second circuit layer 150, the third circuit layer 170, and the upper electrode 113 are formed.

According to an exemplary embodiment of the present disclosure, the second circuit layer 150 is formed by patterning the second metal layer 151 and the second plating layer 152. In addition, the third circuit layer 170 and the upper electrode 113 are formed by patterning the carrier metal layer 220 and the first plating layer 171. For example, an etching resist (not shown) having an opening part formed therein is first formed on the first plating layer 171 and the second plating layer 152. The etching resist (not shown) is patterned to protect regions on which circuit patterns of the second circuit layer 150 and the third circuit layer 170 and the upper electrode 113 are to be formed and to position opening parts in regions from which the circuit patterns and the upper electrode 113 are to be removed. Next, the second circuit layer 150 is formed by removing the second metal layer 151 and the second plating layer 152 exposed by the opening parts of the etching resist (not shown) and removing the etching resist (not shown). In addition, the third circuit layer 170 and the upper electrode 113 are formed by removing the carrier metal layer 220 and the first plating layer 171 exposed by the opening parts of the etching resist (not shown) and removing the etching resist (not shown). The capacitor 110 according to an exemplary embodiment of the present disclosure is formed by the above-mentioned processes.

The capacitor 110 according to an exemplary embodiment of the present disclosure includes the lower electrode 112, the dielectric layer 111, and the upper electrode 113. Here, the lower electrode 112 and the dielectric layer 111 are buried in the first insulating layer 120. In addition, only the upper electrode 113 is protruded from the first insulating layer 120 and is formed on the same layer as the third circuit layer 170.

According to an exemplary embodiment of the present disclosure, the capacitor 110, which is formed by a process of forming the package substrate 100, is formed simultaneously when the package substrate 100 is formed. Therefore, a process of forming a cavity for embedding an external capacitor in the substrate is omitted. That is, in the package substrate 100 according to an exemplary embodiment of the present disclosure, the number of processes and the processing time may be reduced.

In addition, since a buried pattern (first circuit layer) may be implemented using the carrier substrate, a pattern having a fine pitch may be easily formed and a thickness of the package substrate 100 may be reduced. Since the package substrate 100 may have the reduced thickness, it may be used as a substrate of a package in which a memory device is mounted on a package on package.

Referring to FIG. 11, the solder resist 180 is formed.

The solder resist 180 according to an exemplary embodiment of the present disclosure is formed to surround the first insulating layer 120, the second insulating layer 140, the second circuit layer 150, the third circuit layer 170, and the capacitor 110 except for a region connected to the outside. The solder resist 180 is formed to protect the package substrate 100 from an external environment.

Although the manufacturing method of the package substrate according to an exemplary embodiment of the present disclosure shows and illustrates a case in which the package substrate is formed on one surface of the carrier substrate, the present disclosure is not limited thereto. That is, the package substrate according to an exemplary embodiment of the present disclosure may be simultaneously formed on both surfaces of the carrier substrate. As such, in the case in which the package substrate is formed on both surfaces of the carrier substrate, two package substrates are simultaneously formed.

### Package

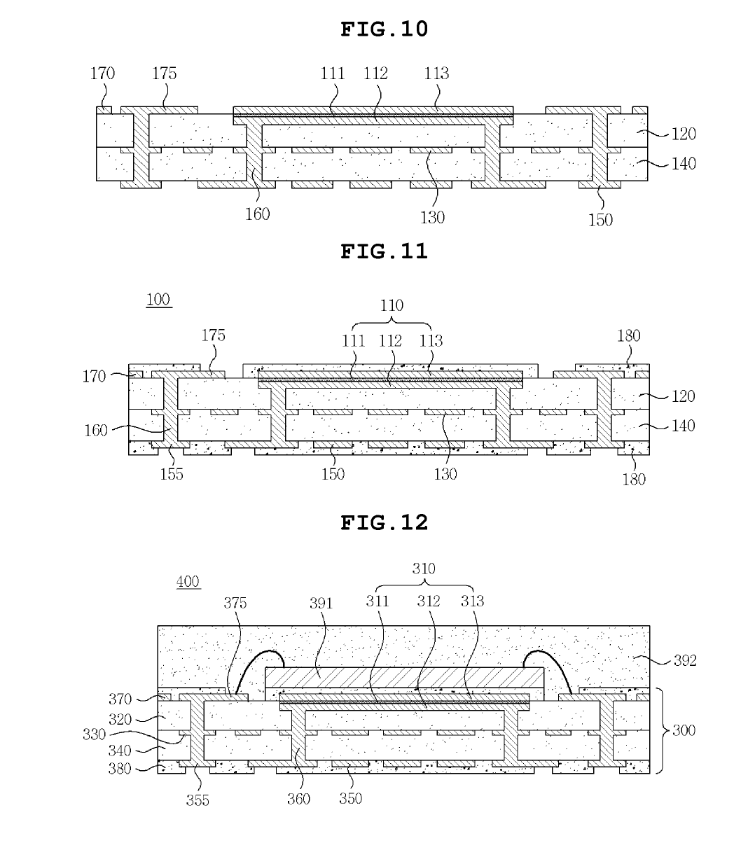

FIG. 12 is a view showing a package according to an exemplary embodiment of the present disclosure.

Referring to FIG. 12, a package 400 according to an exemplary embodiment of the present disclosure includes a package substrate 300, a device 391, and a molding part 392.

The package substrate 300 according to an exemplary embodiment of the present disclosure includes a first insulating layer 320, a second insulating layer 340, first circuit layer 330 to third circuit layer 370, a capacitor 310, a via 360, and a solder resist 380.

According to an exemplary embodiment of the present disclosure, the first insulating layer 320 and the second insulating layer 340 may be made of a complex polymer resin typically used as an interlayer insulating material. For example, the first insulating layer 320 and the second insulating layer 340 may be formed of a prepreg, Ajinomoto Build up Film (ABF), and an epoxy based resin such as FR-4, Bismaleimide Triazine (BT), or the like. However, a material forming the first insulating layer 320 and the second insulating layer 340 according to an exemplary embodiment of the present disclosure is not limited thereto, and may be selected from insulating materials known in the field of circuit board.

As shown in FIG. 12, the first insulating layer 320 may be formed on an upper portion of the second insulating layer 340.

According to an exemplary embodiment of the present disclosure, the first circuit layer 330 is formed to be buried in the upper portion of the second insulating layer 340.

According to an exemplary embodiment of the present disclosure, the second circuit layer 350 is formed to be protruded from a lower portion of the second insulating layer 340. According to an exemplary embodiment of the present disclosure, the second circuit layer 350 includes an external connection pad 355. The package substrate 300 according to an exemplary embodiment of the present disclosure and another package substrate (not shown) are electrically connected to each other through the external connection pad 355.

According to an exemplary embodiment of the present disclosure, the third circuit layer 370 is formed to be protruded from an upper portion of the first insulating layer 320. The third circuit layer 370 according to an exemplary embodiment of the present disclosure includes a bonding pad 375. The bonding pad 375 is electrically connected to device 391 when the device 391 is mounted on an upper portion of the package substrate 300. For example, the bonding pad 375 may be connected to the device 391 by a wire bonding scheme.

The first circuit layer 330 to the third circuit layer 370 according to an exemplary embodiment of the present disclosure may be made of a conductive material. For example, the first circuit layer 330 to the third circuit layer 370 are made of copper (Cu). However, a material forming the first circuit layer 330 to the third circuit layer 370 is not limited to copper and any material may be used without being limited as long as it is used as a conductive material for a circuit in the field of circuit board.

In addition, according to an exemplary embodiment of the present disclosure, one layer of the first circuit layer 330 to the third circuit layer 370 may be a power layer and another of the layers may be a ground layer.

According to an exemplary embodiment of the present disclosure, the capacitor 310 is a thin film capacitor having a three-layer structure. The capacitor 310 according to an exemplary embodiment of the present disclosure includes an upper electrode 313, a lower electrode 312, and a dielectric layer 311. Here, the dielectric layer 311 is disposed between the upper electrode 313 and the lower electrode 312.

The upper electrode 313 of the capacitor 310 according to an exemplary embodiment of the present disclosure is formed on the upper portion of the first insulating layer 320. That is, the upper electrode 313 of the capacitor 310 and the third circuit layer 370 are formed on the same layer. In addition, the dielectric layer 311 and the lower electrode 312 are buried in the first insulating layer 320.

According to an exemplary embodiment of the present disclosure, the upper electrode 313 of the capacitor 310 formed as described above is bonded to a portion of the third circuit layer 370 formed on the same layer. For example, the portion of the third circuit layer 370 bonded to the capacitor 310 may be the bonding pad 375. In addition, in the case in which the third circuit layer 370 bonded to the capacitor 310 is the power layer, the upper electrode 313 of the capacitor 310 may also serve as the power layer.

According to an exemplary embodiment of the present disclosure, the via 360 electrically connects at least two of the first to third circuit layers 330 to 370 and the capacitor 310 to each other.

Referring to FIG. 12, the via 360 according to an exemplary embodiment of the present disclosure electrically connects the lower electrode 312 of the capacitor 310 and the first and second circuit layers 330 and 350 to each other. In addition, the via 360 electrically connects the second circuit layer 350 and the third circuit layer 370 to each other. Although not shown in FIG. 12, the via 360 may connect the first circuit layer 330 and the second circuit layer 350 to each other or the first circuit layer 330 and the third circuit layer 370 to each other.

According to an exemplary embodiment of the present disclosure, the solder resist 380 is formed to surround the second circuit layer 350, the third circuit layer 370, and the capacitor 310 except for a region connected to the outside. Here, the region connected to the outside is the bonding pad 375 and the external connection pad 355.

According to an exemplary embodiment of the present disclosure, the device 391 is a memory device. However, a kind of device 391 is not limited to the memory device, and any kind of device may be used as long as it is used in the package. The device 391 according to an exemplary embodiment of the present disclosure is formed on an upper portion of the solder resist 380. In this case, the device 391 is positioned on an upper portion of the capacitor 310. In addition, the device 391 is electrically connected to the bonding pad 375 of the second circuit layer 350. For example, the device 391 and the bonding pad 375 are electrically connected to each other by a wire bonding scheme.

According to an exemplary embodiment of the present disclosure, a signal of the device 391 is transmitted to the bonding pad 375 through a wire and is transmitted to the upper electrode 313 bonded to the bonding pad 375. That is, a signal transmitting distance between the device 391 and the capacitor 310 is reduced. As such, noise shielding effect may be improved by the reduction in the signal transmitting distance between the device 391 and the capacitor 310.

According to an exemplary embodiment of the present disclosure, the molding part 392 is formed to surround the package substrate 300 and the device 391. The molding part 392 is formed to protect the package substrate 300 and the device 391 from an external environment. For example, the molding part 392 may be made of an epoxy molding compound (EMC). However, a material of the molding part 392 is not limited to the EMC, and any kind of material may be used as long as it is a molding material used in the package field.

An exemplary embodiment of the present disclosure has illustrated a case in which the package substrate 300 used in the package 400 is formed by the insulating layer of the two layers and the circuit layer of the three layers. However, the number of layers of the package substrate 300 used in the package 400 is not limited thereto, and may be variously implemented according to a selection of those skilled in the art.

### Package on Package

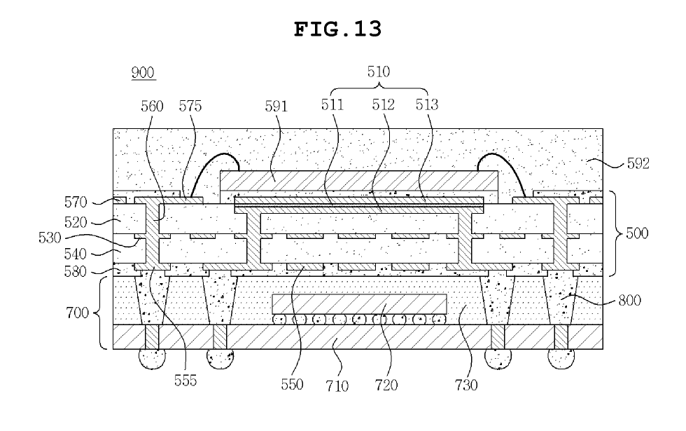

FIG. 13 is a view showing a package on package 900 according to an exemplary embodiment of the present disclosure.

Referring to FIG. 13, the package on package 900 according to an exemplary embodiment of the present disclosure includes a first package 600, a second package 700, and a connection terminal 800. In addition, the package on package 900 has a structure in which the first package 600 and the second package 700 are stacked. For example, the first package 600 is stacked on the second package 700.

The first package 600 according to an exemplary embodiment of the present disclosure includes a first package substrate 500, a first device 591, and a first molding part 592.

The first package substrate 500 according to an exemplary embodiment of the present disclosure includes a first upper insulating layer 520, a second upper insulating layer 540, first upper circuit layer 530 to third upper circuit layer 570, a first capacitor 510, a first via 560, and a first solder resist 580.

According to an exemplary embodiment of the present disclosure, the first upper insulating layer 520 and the second upper insulating layer 540 may be made of a complex polymer resin typically used as an interlayer insulating material. For example, the first upper insulating layer 520 and the second upper insulating layer 540 may be formed of a prepreg, Ajinomoto Build up Film (ABF), and an epoxy based resin such as FR-4, Bismaleimide Triazine (BT), or the like. However, a material forming the first upper insulating layer 520 and the second upper insulating layer 540 according to an exemplary embodiment of the present disclosure is not limited thereto, and may be selected from insulating materials known in the field of circuit boards.

As shown in FIG. 13, the first upper insulating layer 520 may be formed on an upper portion of the second upper insulating layer 540.

According to an exemplary embodiment of the present disclosure, the first upper circuit layer 530 is formed to be buried in the upper portion of the second upper insulating layer 540.

According to an exemplary embodiment of the present disclosure, the second upper circuit layer 550 is formed to be protruded from a lower portion of the second upper insulating layer 540. In addition, according to an exemplary embodiment of the present disclosure, the second upper circuit layer 550 includes a first external connection pad 555.

According to an exemplary embodiment of the present disclosure, the third upper circuit layer 570 is formed to be protruded from the upper portion of the first upper insulating layer 520. In addition, according to an exemplary embodiment of the present disclosure, the third upper circuit layer 570 includes a bonding pad 575. The bonding pad 575 is a configuration that is electrically connected to device 591 when the first device 591 is mounted on an upper portion of the package substrate 100. For example, the bonding pad 575 may be connected to the first device 591 by a wire bonding scheme.

The first upper circuit layer 530 to the third upper circuit layer 570 according to an exemplary embodiment of the present disclosure may be made of a conductive material. For example, the first upper circuit layer 530 to the third upper circuit layer 570 are made of copper (Cu). However, a material forming the first upper circuit layer 530 to the third upper circuit layer 570 is not limited to copper and any material may be used without being limited as long as it is used as a conductive material for a circuit in the field of circuit board.

In addition, according to an exemplary embodiment of the present disclosure, one layer of the first upper circuit layer 530 to the third upper circuit layer 570 may be a power layer and another of the layers may be a ground layer.

According to an exemplary embodiment of the present disclosure, the first capacitor 510 is a thin film capacitor having a three-layer structure. The first capacitor 510 according to an exemplary embodiment of the present disclosure includes a first upper electrode 513, a first lower electrode 512, and a first dielectric layer 511. Here, the first dielectric layer 511 is disposed between the first upper electrode 513 and the first lower electrode 512.

The first upper electrode 513 of the first capacitor 510 according to an exemplary embodiment of the present disclosure is formed on the upper portion of the first upper insulating layer 520. That is, the first upper electrode 513 of the first capacitor 510 and the third upper circuit layer 570 are formed on the same layer. In addition, the first dielectric layer 511 and the first lower electrode 512 are formed to be buried in the first upper insulating layer 520.

The first upper electrode 513 according to an exemplary embodiment of the present disclosure as described above is bonded to a portion of the third upper circuit layer 570 formed on the same layer. For example, the portion of the third upper circuit layer 570 bonded to the first capacitor 510 may be the bonding pad 575. In addition, in the case in which the third upper circuit layer 570 bonded to the first capacitor 510 is the power layer, the first upper electrode 513 of the first capacitor 510 may also serve as the power layer.

According to an exemplary embodiment of the present disclosure, the via 560 electrically connects at least two of the first to third upper circuit layers 530 to 570 and the first capacitor 510 to each other.

Referring to FIG. 13, the via 560 according to an exemplary embodiment of the present disclosure electrically connects the first lower electrode 512 of the first capacitor 510 and the first and second upper circuit layers 530 and 550 to each other. In addition, the via 560 electrically connects the second upper circuit layer 550 and the third upper circuit layer 570 to each other. Although not shown in FIG. 13, the via 560 may connect the first upper circuit layer 530 and the second upper circuit layer 550 to each other or the first upper circuit layer 530 and the third upper circuit layer 570 to each other.

According to an exemplary embodiment of the present disclosure, the first solder resist 580 is formed to surround the second upper circuit layer 550, the third upper circuit layer 570, and the first capacitor 510 except for a region connected to the outside. Here, the region connected to the outside is the bonding pad 575 and the first external connection pad 555.

According to an exemplary embodiment of the present disclosure, the first device 591 is a memory device. The first device 591 according to an exemplary embodiment of the present disclosure is formed on an upper portion of the first solder resist 580. In this case, the first device 591 is positioned on an upper portion of the first capacitor 510. In addition, the first device 591 according to an exemplary embodiment of the present disclosure is electrically connected to the bonding pad 575 of the second upper circuit layer 550. For example, the first device 591 and the bonding pad 575 may be electrically connected to each other by a wire bonding scheme.

According to an exemplary embodiment of the present disclosure, a signal of the first device 591 is transmitted to the bonding pad 575 through a wire and is transmitted to the first upper electrode 513 bonded to the bonding pad 575. That is, a signal transmitting distance between the first device 591 and the first capacitor 510 is reduced. In addition, according to an exemplary embodiment of the present disclosure, noise shielding effect may be improved by the reduction in the signal transmitting distance between the first device 591 and the first capacitor 510.

The first molding part 592 according to an exemplary embodiment of the present disclosure is formed to surround the first package substrate 500 and the first device 591. The first molding part 592 is formed to protect the first package substrate 500 and the first device 591 from an external environment. For example, the first molding part 592 may be made of an epoxy molding compound (EMC). However, a material of the first molding part 592 is not limited to the EMC, and any kind of material may be used as long as it is a molding material used in the package field.

An exemplary embodiment of the present disclosure has illustrated a case in which the first package substrate 500 used in the package 400 is formed by the insulating layer of the two layers and the circuit layer of the three layers. However, the number of layers of the first package substrate 500 is not limited thereto, and may be variously implemented according to a selection of those skilled in the art.

According to an exemplary embodiment of the present disclosure, the second package 700 includes a second package substrate 710, a second device 720, and a second molding part 730.

According to an exemplary embodiment of the present disclosure, the second package substrate 710 includes one or more layers of a lower insulating layer (not shown) and a lower circuit layer (not shown).

According to an exemplary embodiment of the present disclosure, a material of the lower insulating layer may be selected from insulating materials known in the field of circuit board. In addition, the lower insulating layer according to an exemplary embodiment of the present disclosure may be formed in one or more layers.

According to an exemplary embodiment of the present disclosure, the lower circuit layer is formed in one or more layers on the lower insulating layer. A material of the lower circuit layer according to an exemplary embodiment of the present disclosure may be used without being limited as long as it is used as a conductive material for a circuit in the field of circuit board.

The lower circuit layer according to an exemplary embodiment of the present disclosure is electrically connected to the second device 720. In this case, the lower circuit layer and the second device 720 may be electrically connected to each other by a wire, a solder ball, or the like. In addition, according to an exemplary embodiment of the present disclosure, an external connection pad (not shown) is formed on the outermost layer of the lower circuit layer. The second package 700 according to an exemplary embodiment of the present disclosure may be electrically connected to the first package 600 through the external connection pad of the second package substrate 710.

According to an exemplary embodiment of the present disclosure, the second device 720 is an application process device. According to an exemplary embodiment of the present disclosure, the second device 720 is positioned on an upper portion of the second package substrate 710.

Although not shown in FIG. 13, a second capacitor (not shown) is disposed inside or outside of the second package substrate 710. As the second capacitor, any kind of capacitors may be used as long as it is used in the field of package. The second capacitor may be connected to the second device 720 through the lower circuit layer. The second capacitor as described above may serve to shield noise for signal transmitting reliability of the second device 720.

In addition, according to an exemplary embodiment of the present disclosure, a second solder resist (not shown) is formed to surround the lower insulating layer and the lower circuit layer except for a region connected to the outside. Here, the region connected to the outside may be a portion of the lower circuit layer connected to the second device 720 and a region connected to the first package 600.

According to an exemplary embodiment of the present disclosure, the second molding part 730 is formed to surround the second package substrate 710 and the second device 720. The second molding part 730 is formed to protect the second package substrate 710 and the second device 720 from an external environment. For example, the second molding part 730 may be made of an epoxy molding compound (EMC). However, a material of the second molding part 730 is not limited to the EMC, and any kind of material may be used as long as it is a molding material used in the package field. In addition, in the case in which the second capacitor is formed outside the second package substrate 710, the second molding part 730 may be formed to cover and protect the second capacitor.

According to an exemplary embodiment of the present disclosure, the connection terminal 800 electrically connects the first package 600 and the second package 700 to each other. According to an exemplary embodiment of the present disclosure, the connection terminal 800 is positioned between the first package 600 and the second package 700. That is, the connection terminal 800 is formed to penetrate through the second molding part 730. Accordingly, an upper portion of the connection terminal 800 is bonded to the first external connection pad 555 of the first package 600 and a lower portion thereof is bonded to a second external connection pad (not shown) of the second package 700.

In the package on package 900 according to an exemplary embodiment of the present disclosure, the package substrate 100 shown in FIG. 1 has been used in the first package 600 on which the memory device is mounted. The package substrate 100 of FIG. 1 is formed according to those described with reference to FIGS. 2 through 11, such that it may be formed in a thin thickness and embed a thin film capacitor therein. Therefore, in the package on package 900 according to an exemplary embodiment of the present disclosure, the capacitors are mounted on the first package 600 on which the memory device is mounted and the second package 700 on which the application process is mounted, respectively, such that an effect of shielding signal noise may be improved.

In addition, in describing the package on package 900 according to an exemplary embodiment of the present disclosure, the first device 591 has been classified as the memory device and the second device 720 has been classified as the application process device. However, kinds of the first device 591 and the second device 720 are not limited thereto, and any device may be used as long as it is used in the package.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A package substrate comprising:
an insulating layer;
a circuit layer formed on the insulating layer; and
a capacitor including a lower electrode, an upper electrode, and a dielectric layer formed between the lower electrode and the upper electrode, the lower electrode and the dielectric layer being buried in the insulating layer and the upper electrode being formed on an upper portion of the insulating layer.

2. The package substrate of claim 1, wherein the insulating layer has a two-layer structure including a first insulating layer and a second insulating layer, and the circuit layer has a three-layer structure including a first circuit layer, a second circuit layer, and a third circuit layer.

3. The package substrate of claim 2, wherein one layer of the first to third circuit layers is formed on the same layer as the upper electrode of the capacitor.

4. The package substrate of claim 2, wherein one layer of the first to third circuit layers is formed to be buried in an upper portion of the first insulating layer.

5. The package substrate of claim 2, wherein the first circuit layer is formed to be buried in an upper portion of the second insulating layer, the second circuit layer is formed on a lower portion of the second insulating layer, and the third circuit layer is formed on an upper portion of the first insulating layer.

6. The package substrate of claim 2, wherein one layer of the first to third circuit layers is a ground layer and another layer of the first to third circuit layers is a power layer.

7. The package substrate of claim 2, further comprising a via electrically connecting at least one layer of the first to the third layers and the capacitor to each other.

8. The package substrate of claim 1, wherein the circuit layer has a portion thereof bonded to the upper electrode of the capacitor.

9. The package substrate of claim 1, further comprising a solder resist formed to surround the insulating layer, the circuit layer, and the capacitor except for a region connected to the outside.

10. A package comprising:
an insulating layer;
a circuit layer formed on the insulating layer;
a capacitor including a lower electrode, an upper electrode, and a dielectric layer formed between the lower electrode and the upper electrode, the lower electrode and the dielectric layer being buried in the insulating layer and the upper electrode being formed on an upper portion of the insulating layer; and
a device formed on the upper portion of the insulating layer and electrically connected to the circuit layer.

11. The package of claim 10, wherein the insulating layer has a two-layer structure including a first insulating layer and a second insulating layer, and the circuit layer has a three-layer structure including a first circuit layer, a second circuit layer, and a third circuit layer.

12. The package of claim 11, wherein one layer of the first to third circuit layers is formed on the same layer as the upper electrode of the capacitor.

13. The package of claim 11, wherein one layer of the first to third circuit layers is formed to be buried in an upper portion of the first insulating layer.

14. The package of claim 11, wherein the first circuit layer is formed to be buried in an upper portion of the second insulating layer, the second circuit layer is formed on a lower portion of the second insulating layer, and the third circuit layer is formed on an upper portion of the first insulating layer.

15. The package of claim 11, wherein one layer of the first to third circuit layers is a ground layer and another layer of the first to third circuit layers is a power layer.

16. The package of claim 10, further comprising a via electrically connecting the circuit layer and the capacitor to each other.

17. The package of claim 10, wherein the circuit layer has a portion thereof bonded to the upper electrode of the capacitor.

18. The package of claim 10, further comprising a solder resist formed to surround the insulating layer, the circuit layer, and the capacitor except for a region connected to the outside.

19. The package of claim 10, wherein the device and the circuit layer are connected to each other by a wire.

20. The package of claim 10, further comprising a molding part formed to surround the insulating layer, the circuit layer, the capacitor, and the device.

21. A package on package comprising:
a first package including
an upper insulating layer,
an upper circuit layer formed on the upper insulating layer,
a first capacitor including a lower electrode, an upper electrode, and a dielectric layer formed between the lower electrode and the upper electrode, the lower electrode and the dielectric layer being buried in the upper insulating layer and the upper electrode being formed on an upper portion of the upper insulating layer, and
a first device formed on the upper portion of the upper insulating layer and electrically connected to the upper circuit layer;
a second package including
a lower insulating layer,
a lower circuit layer formed on the lower insulating layer, and
a second device formed on the lower insulating layer and electrically connected to the lower circuit layer; and
a connection terminal positioned between the first package and the second package and electrically connecting the first package and the second package to each other.

22. The package on package of claim 21, wherein the upper insulating layer has a two-layer structure including a first upper insulating layer and a second upper insulating layer, and the upper circuit layer has a three-layer structure including a first upper circuit layer, a second upper circuit layer, and a third upper circuit layer.

23. The package on package of claim 22, wherein one layer of the first to third upper circuit layers is formed on the same layer as the upper electrode of the first capacitor.

24. The package on package of claim 22, wherein one layer of the first to third upper circuit layers is formed to be buried in an upper portion of the first upper insulating layer.

25. The package on package of claim 22, wherein the first upper circuit layer is formed to be buried in an upper portion of the second upper insulating layer, the second upper circuit layer is formed on a lower portion of the second upper insulating layer, and the third upper circuit layer is formed on an upper portion of the first upper insulating layer.

26. The package on package of claim 22, wherein one layer of the first to third upper circuit layer is a ground layer and another of the first to third circuit layers is a power layer.

27. The package on package of claim 21, further comprising a via electrically connecting the upper circuit layer and the first capacitor to each other.

28. The package on package of claim 21, wherein the upper circuit layer has a portion thereof bonded to the upper electrode of the first capacitor.

29. The package on package of claim 21, further comprising a first solder resist formed to surround the upper insulating layer, the upper circuit layer, and the first capacitor except for a region connected to the outside.

30. The package on package of claim 21, wherein the first device and the upper circuit layer are connected to each other by a wire.

31. The package on package of claim 21, wherein the first package further includes a first molding part formed to surround the upper insulating layer, the upper circuit layer, the first capacitor, and the first device.

32. The package on package of claim 21, wherein the second package further includes a second capacitor formed on the lower insulating layer.

33. The package on package of claim 21, wherein the second package further includes a second solder resist formed to surround the lower insulating layer, the lower circuit layer, a second capacitor.

34. The package on package of claim 21, wherein the second package further includes a second molding part formed to surround the lower insulating layer, the lower circuit layer, a second capacitor, and the second device.

35. A manufacturing method of a package substrate, the method comprising:
forming a dielectric layer on a region of a portion of a carrier substrate;
forming a lower electrode on the dielectric layer;
forming a first insulating layer on the carrier substrate such that the insulating layer is burying the dielectric layer and the lower electrode;
forming a first circuit layer on the first insulating layer;
forming a second insulating layer on the first circuit layer;
removing the carrier substrate; and
forming a second circuit layer, an upper electrode, and a third circuit layer on the second insulating layer, the dielectric layer, and the first insulating layer, respectively.

36. The manufacturing method of claim 35, further comprising, in the forming of the first circuit layer, forming a via electrically connecting the lower electrode and the first circuit layer to each other.

37. The manufacturing method of claim 35, further comprising, in the forming of the second circuit layer, the upper electrode, and the third circuit layer, forming a via electrically connecting at least two of the first circuit layer, the second circuit layer, the third circuit layer, and the lower electrode.

38. The manufacturing method of claim 35, wherein in the forming of the second circuit layer, the upper electrode, and the third circuit layer, a portion of the third circuit layer and an upper electrode are electrically connected to each other.

39. The manufacturing method of claim 35, wherein one layer of the first circuit layer to the third circuit layer is a ground layer and another layer of the first to third circuit layers is a power layer.

40. The manufacturing method of claim 35, further comprising, after the forming of the second circuit layer, the upper electrode, and the third circuit layer, forming a solder resist formed to surround the first circuit layer to the third circuit layer and the upper electrode except for a region connected to the outside.

41. A package substrate comprising:
an insulating layer; and
a capacitor including a lower electrode, an upper electrode, and a dielectric layer formed between the lower electrode and the upper electrode, the lower electrode and the dielectric layer being recessed in the insulating layer from a first surface of the insulating layer, and the upper electrode being a portion of the capacitor protruded out of the first surface of the insulating layer.

42. The package substrate of claim 41, further comprising
a lower circuit layer formed on a second surface of the insulating layer opposite to the first surface of the insulating layer;
a via located between and electrically connecting the lower electrode of the capacitor to the lower circuit layer; and
an upper circuit layer formed on the first surface of the insulating layer and substantially coplanar with the upper electrode of the capacitor.

43. A package on package comprising:
a first package comprising
the package substrate of claim 42, and
a solder resist covering the capacitor;
a first device on top of the solder resist and electrically connected to the upper circuit layer;
a second package including a second package substrate, a second device on the second package substrate; and
a connection terminal positioned between the first package and the second package and electrically connecting the first package and the second package to each other.

44. A method of manufacturing the package substrate of claim 41, comprising:
forming the dielectric layer on a region of a portion of a carrier substrate;
forming the lower electrode on the dielectric layer;
forming a first insulating layer on the carrier substrate such that the insulating layer is burying the dielectric layer and the lower electrode;
removing the carrier substrate; and
forming the upper electrode on the dielectric layer.
